(19) United States
(12) Patent Application Publication
(10) Pub. No.: US 2022/0228290 A1
(43) Pub. Date: Jul. 21, 2022

(54) CRUCIBLE, CRYSTAL BODY, AND OPTICAL ELEMENT

(71) Applicant: TDK CORPORATION, Tokyo (JP)

(72) Inventor: Katsumi KAWASAKI, Tokyo (JP)

(73) Assignee: TDK CORPORATION, Tokyo (JP)

(21) Appl. No.: 17/577,900

(22) Filed: Jan. 18, 2022

(30) Foreign Application Priority Data
Jan. 19, 2021 (JP) 2021-006205

(51) Int. Cl. C30B 15/10; C30B 15/08

(52) U.S. Cl. CPC C30B 15/10; C30B 15/08

(57) ABSTRACT

Provided is a crucible including: a melt reservoir that collects a melt that becomes a raw material of a crystal; and a nozzle portion that controls a shape of the crystal. The nozzle portion includes nozzle holes that allow the melt to flow out from the melt reservoir to an end surface of the nozzle portion. Surface roughness of an inner peripheral surface of the nozzle holes is 10 μm or less.

### BACKGROUND OF THE INVENTION

### 1. Field of the Invention

The present invention relates to a crucible that is used in, for example, a micro pulling-down method (hereinafter, also referred to as “μ-PD method”) or the like, a crystal body that is grown by using the crucible, and an optical element using the crystal body.

### 2. Description of the Related Art

The μ-PD method is a kind of method in which a raw material melt passing through a nozzle hole formed in the bottom of a crucible is brought into contact with a seed crystal, and then the seed crystal is moved downward to grow a crystal. Since the uniform raw material melt in the crucible is continuously and forcibly discharged from the nozzle hole for crystallization, there is a characteristic in which a composition fluctuation in a crystal growth direction is small.

In addition, the nozzle hole is provided, and a shape of a crystal growth surface can be defined by a shape of a nozzle surface on which the raw material melt that has passed through the nozzle hole and has been discharged to the outside of the crucible wets and spreads, and thus a crystal with high shape accuracy during crystal growth can be obtained.

With regard to a single crystal material, a hetero-element (dopant) other than a single crystal constituent element is added as a means for applying desired material characteristics in many cases. Particularly, in optical crystals such as an optical crystal for a laser, a nonlinear optical crystal, a luminescent crystal for a scintillator, and a fluorescent crystal, optical characteristics greatly vary due to the dopant, and thus a dopant concentration distribution in the crystal greatly acts on the optical characteristics of the entirety of the crystal.

In a crucible described in JP 2008-239352 A, a plurality of nozzle holes are provided in an end surface of a nozzle so as to make an additive element in a crystal uniform. However, with regard to a configuration of the crucible in the related art, the present inventors have found that a variation of the additive element in a grown crystal is large, particularly, in a case where an element having a segregation coefficient less than 1 is set as the additive element.

### SUMMARY OF THE INVENTION

The present invention has been made in consideration such circumstances, and an object thereof is to provide a crucible capable of obtaining a crystal body in which a variation of an additive element in the crystal body is small, a crystal body obtained by using the crucible, and an optical element using the crystal body.

As a result of thorough investigation for accomplishing the object, the present inventors have found that when surface roughness of an inner surface of a nozzle hole is set to a predetermined value or less, particularly, even in an additive element having a segregation coefficient less than 1, the additive element is uniformly dispersed inside a crystal body, and they accomplished the present invention.

That is, according to an aspect of the present invention, there is provided a crucible including:

a melt reservoir storing a melt to be a raw material of a crystal; and

a nozzle portion controlling a shape of the crystal,

The nozzle portion includes a nozzle hole guiding the melt from the melt reservoir to an end surface of the nozzle portion.

A surface roughness of an inner peripheral surface of the nozzle hole is 10 μm or less.

According to the crucible of the present invention, since the surface roughness of the inner peripheral surface of the nozzle hole is set to a predetermined value or less, particularly, even in an additive element having a segregation coefficient less than 1, the additive element can be uniformly dispersed into the crystal body. Although the reason for this is not clear, for example, it is considered as follows.

In order to uniformly disperse an additive element into the crystal body, a configuration in which a plurality of nozzle holes are provided in a nozzle end of the crucible, and a melt is ejected from the nozzle holes onto a crystal growth plane is suggested. However, in a crucible in the related art, since attention was not paid to surface roughness of an inner peripheral surface of the nozzle holes, it was difficult to uniformly disperse an additive element into the crystal body due to occurrence of a difference in the flowing amount of the melt between the nozzle holes, and the like.

In the crucible of the present invention, since the surface roughness of the inner peripheral surface of the nozzle holes is set to a predetermined value or less, flowing-out of the melt from the nozzle holes becomes stable, and the amount of the melt flowing from the nozzle holes becomes approximately uniform. Accordingly, it is considered that the additive element is uniformly and easily dispersed into the crystal body. Furthermore, even in a case where a single nozzle hole is formed in a nozzle end of the crucible, flowing-out of the melt from the nozzle hole becomes more stable in comparison to a crucible in the related art in which the surface roughness of the inner peripheral surface of the nozzle hole is not managed, and thus it is easy to uniformly disperse the additive element into the crystal body.

Preferably, the nozzle portion is an assembly of divided parts, and the nozzle holes are formed by combining grooves formed in matching surfaces of the divided parts.

The crucible is required to have heat resistance to withstand a temperature of the melt, possibility of inductive heating, and the like, and thus the crucible is constituted, for example, by a metal that is difficult to be machined, or the like in many cases. Therefore, machining of the nozzle holes formed in the crucible becomes difficult, and it is difficult to set the surface roughness of the inner peripheral surface of the nozzle holes to 10 μm or less.

In a preferred aspect of the present invention, grooves which constitute the nozzle holes are formed in matching surfaces of divided parts, and the nozzle holes are formed by combining the divided parts. Differently from machining of a hole, when machining a groove, since a machining surface is exposed to the outside, it is easy to obtain accuracy of the surface roughness, and it is easy to set the surface roughness to 10 μm or less, 5 μm or less, or 1 μm or less. Accordingly, grooves are combined to form the nozzle holes by combining the divided parts, and it is easy to set the surface roughness of the inner peripheral surface of the nozzle holes to a predetermined value or less.

A plurality of grooves may be formed in the matching surfaces of the divided parts, and the divided parts may be combined to form a plurality of nozzle holes. Due to machining of the grooves, it is easy to obtain accuracy of surface roughness and it is also easy to make accuracy of the surface roughness of a plurality of grooves substantially uniform. Accordingly, the amount of the melt flowing from the nozzle holes becomes substantially uniform, and thus it is easier to uniformly disperse an additive element into the crystal body.

Preferably, the grooves extend from the melt reservoir to the end surface of the nozzle portion in the middle of the matching surfaces or at end corners, and the grooves define a part of the inner peripheral surface of the nozzle holes. According to this configuration, it is easy to set the surface roughness of the inner peripheral surface of the nozzle holes to a predetermined value or less.

Preferably, the divided parts comprise a first part having an outer side surface of the nozzle portion, and a second part that is combined to the first part. When combining the second part to the first part that constitutes the outer side surface of the nozzle portion, it is possible to easily form the nozzle portion including nozzle holes having a smooth inner peripheral surface of which surface roughness is a predetermined value or less. Note that, the second part may be formed by combining divided parts.

Preferably, the first part is integrated with the melt reservoir, and the second part is formed to be detachable from the melt reservoir. According to this configuration, the nozzle portion can be easily formed. In addition, since the melt reservoir and the first part are integrated with each other, the melt reliably leaks from the end surface of the nozzle portion.

Preferably, an inner side surface of the first part is inclined from the melt reservoir toward a direction close to the center of the end surface of the nozzle portion.

An outer side surface of the second part is inclined in correspondence with the inner side surface of the first part.

The inner side surface of the first part and the outer side surface of the second part are faced to each other and are combined.

According to this configuration, when the second part is inserted into an opening of the first part and is dropped down, the second part does not fall down, and the nozzle portion can be easily formed. In addition, the outer side surface of the second part and the inner side surface of the first part become matching surfaces, and the grooves are formed in the matching surfaces, and thus the nozzle holes inclined toward a direction close to the center of an end surface of the nozzle portion from the melt reservoir can be easily formed by combining the first part and the second part.

Preferably, the inner peripheral surface is coated with a wettability improving layer having high wettability with the melt stored in the melt reservoir. According to this configuration, it is easy for the melt to flow out to the end surface after passing through the nozzle holes, and thus a variation of an additive element in a crystal body can be effectively suppressed.

Preferably, the crucible is made from iridium, rhenium, molybdenum, tantalum, tungsten, platinum, or alloys thereof. The metals (including the alloys) are excellent in heat resistance, are easily inductively heated, and are preferably used as a crucible. In addition, when using the crucible formed from the materials, a crystal with a high melting point can be manufactured.

However, typically, the materials are difficult to be machined, but in the configuration of the preferred crucible of the present invention, a hole is not formed by machining the metals, grooves are formed in an outer surface of divided parts, and the nozzle holes are formed by combining the divided parts. Accordingly, it is easy to machine the surface roughness of the inner peripheral surface of the nozzle holes with accuracy of a predetermined value or less.

According to another aspect of the present invention, there is provided a crystal body (preferably, a single crystal) that is manufactured by using the crucible. The crystal body may contain an additive element having a segregation coefficient less than 1. A crystal that is grown by using the crucible according to the present invention has a shape close to an ideal columnar shape. Furthermore, a different phase is less likely to be mixed in the crystal body, and the crystal body is further less likely to be polycrystallized.

In addition, according to still another aspect of the present invention, there is provided a method of manufacturing a crystal body, including:

a process of causing a melt that becomes a raw material of a crystal to flow out from nozzle hole outlets of nozzle holes which are formed in a nozzle portion and in which surface roughness of an inner peripheral surface is 10 μm or less.

According to the manufacturing method of the present invention, even in a case where an additive element having a segregation coefficient less than 1 is contained, it is possible to obtain a crystal body in which a concentration variation of the additive element is suppressed. In the crystal body obtained by the manufacturing method of the present invention, crystallinity is improved, a single crystal is likely to be obtained, polycrystallization can be suppressed, and occurrence of cracks is also suppressed.

In addition, the crystal body obtained by using the manufacturing method of the present invention is preferably used as an optical element.

Furthermore, when using the method of the present invention, stabilization of crystal growth is secured, and shape accuracy of the crystal body is improved. Accordingly, a machining loss of the crystal body decreases, and a crystal body with high quality can be manufactured with high efficiency.

### BRIEF DESCRIPTION OF THE DRAWINGS

FIG. 1 is a schematic cross-sectional view of a crystal manufacturing device including a crucible according to an embodiment of the present invention;

FIG. 2 is an enlarged cross-sectional view of a portion II of the crucible illustrated in FIG. 1;

FIG. 3 is a partial cross-sectional perspective view of the crucible illustrated in FIG. 1;

FIG. 4A is a schematic exploded perspective view illustrating a configuration of a nozzle portion illustrated in FIG. 2 in detail;

FIG. 4B is a plan view taken along line IVB-IVB of an end surface of the nozzle portion illustrated in FIG. 2;

FIG. 5A is a plan view of an end surface of a nozzle portion in a crucible according to another embodiment of the present invention;

FIG. 5B is a plan view of an end surface of a nozzle portion in a crucible according to still another embodiment of the present invention;

FIG. 6 is an enlarged cross-sectional view of a crucible according to still another embodiment of the present invention; and

FIG. 7 is a graph illustrating comparison of a deviation in concentration of an additive element related to examples of the present invention and a comparative example.

### DETAILED DESCRIPTION OF THE PREFERRED EMBODIMENTS

Hereinafter, the present invention will be described on the basis of embodiment illustrated in the accompanying drawings.

### First Embodiment

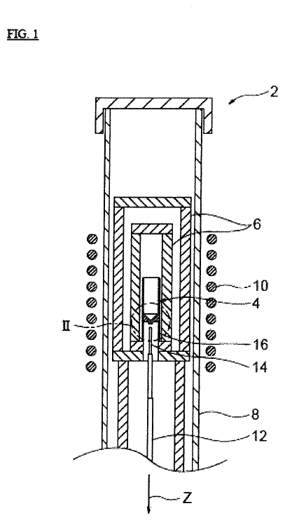

As illustrated in FIG. 1, a crystal manufacturing device 2 of this embodiment includes a crucible 4 and a refractory furnace 6. The crucible 4 will be described later. The refractory furnace 6 is constituted by a refractory material, and covers the periphery of the crucible 4 in a dual manner. An observation window for observing a pulling-down state of a melt from the crucible 4 may be formed in the refractory furnace 6.

The refractory furnace 6 is further covered with an outer casing 8, and a main heater 10 configured to heat the entirety of the crucible 4 is provided at an outer periphery of the outer casing 8. In this embodiment, the outer casing is formed from, for example, a quartz tube, and an inductive heating coil 10 is used as the main heater 10. A seed crystal 14 held by a seed crystal holding jig 12 is disposed on a downward side of the crucible 4. As the seed crystal 14, the same crystal or the same kind of crystal as a crystal to be manufactured is used. For example, in a case where the crystal to be manufactured is a Ce-doped YAG crystal, a YAG single crystal or the like that does not contain an additive is used.

A material of the seed crystal holding jig 12 is not particularly limited, and it is preferable that the material is composed of dense alumina or the like that is less affected in the vicinity of 1900° C. that is a use temperature. A shape and a size of the seed crystal holding jig 12 are not particularly limited, but a rod-shape having a diameter that does not contact with the refractory furnace 6 is preferable.

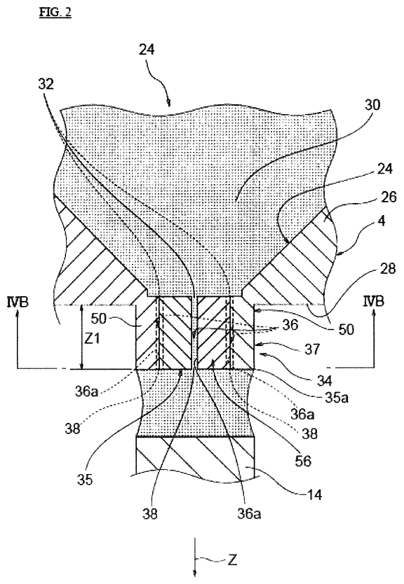

A tubular after-heater 16 is provided at an outer periphery of a lower end of the crucible 4. An observation window may be formed in the after-heater 16 at the same position as in the observation window of the refractory furnace 6. The after-heater 16 is used in a state of being connected to the crucible 4, and is disposed so that a nozzle hole outlet 38 of a nozzle portion 34 of the crucible 4 illustrated in FIG. 2 is located in an internal space of the tubular after-heater 16 so as to heat a melt that is pulled down from the nozzle portion 34 and the nozzle hole outlet 38. For example, the after-heater 16 illustrated in FIG. 1 is constituted by a similar material (it is not necessary to be the same) as in the crucible 4, or the like. When the after-heater 16 is inductively heated by the high-frequency coil 10 in a similar manner as in the crucible 4, radiant heat is generated from an outer surface of the after-heater 16, and the inside of the heater 16 can be heated.

Note that, although not illustrated in the drawings, the crystal manufacturing device 2 is provided with a pressure reducing unit configured to reduce a pressure inside the refractory furnace 6, a pressure measuring unit configured to monitor the pressure reduction, a temperature measuring unit configured to measure a temperature of the refractory furnace 6, and a gas supply unit configured to supply an inter gas to the inside of the refractory furnace 6, and the like.

The material of the crucible 4 is preferably iridium, rhenium, molybdenum, tantalum, tungsten, platinum, or an alloy thereof because a melting point of a crystal is high. In addition, the crucible 4 may be formed from carbon. In a case where the crucible 4 is indirectly heated by heat generation of a member other than the crucible 4, it is preferable that the crucible 4 does not react with a melt of a material that is crystallized, and a phenomenon such as softening at a melting point, or the like does not occur in the crucible 4. In a case where the crucible 4 becomes a heat generating body due to inductive heating (high-frequency heating) or the like, a material that further has electrical conductivity and is heated by an external magnetic field is preferable. Examples thereof include iridium (Ir), molybdenum (Mo), tungsten (W), rhenium (Re), platinum (Pt), and a platinum alloy. In addition, it is more preferable to use iridium (Ir) as the material of the crucible 4 in order to prevent foreign matters from being mixed into a crystal due to oxidation of the material of the crucible 4.

Note that, in a case where a material having a melting point of 1500° C. or lower is set as a target, Pt can be used as the material of the crucible 4. In addition, in a case of using Pt as the material of the crucible 4, crystal growth in the air is possible. In a case where a material having a high melting point higher than 1500° C., since Ir or the like is used as the material of the crucible 4, crystal growth is preferably performed under an inert gas atmosphere such as Ar. A material of the refractory furnace 6 is not particularly limited, but the material is preferably alumina from the viewpoint of a heat retention property, an operating temperature, and prevention of mixing of impurities into a crystal.

Next, the crucible 4 that is used in the crystal manufacturing device 2 of this embodiment will be described in detail. As illustrated in FIG. 2, the crucible 4 according to this embodiment includes a melt reservoir 24 configured to store a melt 30 that becomes a raw material of a crystal, and a nozzle portion 34 that controls a crystal shape. Note that, in a case where the crucible 4 has a large size, a plurality of members may be jointed in the middle of a longitudinal direction of the melt reservoir 24 so as to constitute the crucible 4. The melt reservoir 24 includes a bottomed tubular accommodation wall 26. A constant amount of melt 30 can be stored in the melt reservoir 24 on an inner surface of the accommodation wall 26.

In this embodiment, the crucible 4 is used in a μ-PD method, the nozzle portion 34 is located on a lower side of the melt reservoir 24 in a vertical direction, and the melt 30 stored in the melt reservoir 24 is pulled down by the seed crystal 14 from the nozzle hole outlet 38 formed in the lower end surface 35 of the nozzle portion 34 to a lower side in the vertical direction.

The nozzle portion 34 includes a nozzle outer side surface 37 that protrudes from approximately the central portion of a bottom outer surface 28 of the accommodation wall 26 that constitutes the melt reservoir 24. The lowest end of the nozzle outer side surface 37 intersects the lower end surface 35 of the nozzle portion 34, and a corner located at a boundary between the lower end surface 35 and the outer side surface 37 becomes an outer peripheral edge 35a of the lower end surface 35.

As a result, the lower end surface 35 of the nozzle portion 34 protrudes by a predetermined distance Z1 from the bottom outer surface 28 of the accommodation wall 26 toward a vertical direction (pulling-down direction Z). The predetermined distance Z1 is preferably determined in order for the melt pulled down from the nozzle hole outlet 38 not to adhere to the bottom outer surface 28. The predetermined distance Z1 is preferably 1 to 5 mm, and more preferably 1 to 2 mm. The nozzle portion 34 includes a nozzle hole 36 that allows the melt to flow out from the melt reservoir 24 that stores the melt to the lower end surface 35 of the nozzle portion 34. The lower end surface 35 of the nozzle portion 34 is a surface that is substantially orthogonal to the pulling-down direction Z and is flat.

A bottom inner surface of the accommodation wall 26 that constitutes the melt reservoir 24 includes an inclined surface that is inclined in a taper shape toward the nozzle portion 34 located at the center, and the melt 30 stored in the reservoir 24 flows in toward a nozzle hole inlet 32 of each of a plurality of the nozzle holes 36 formed in the nozzle portion 34. Each of the nozzle holes 36 includes the nozzle hole inlet 32 opened toward the bottom of the melt reservoir 24, and the nozzle hole outlet 38 that is opened at the lower end surface 35 of the nozzle portion 34.

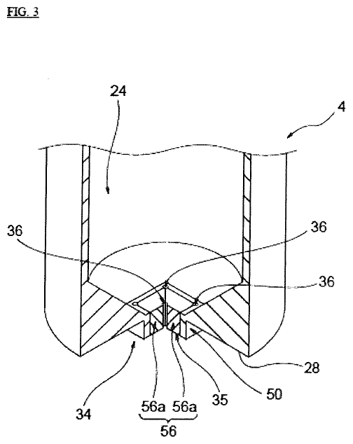

As illustrated in FIG. 3, the nozzle portion 34 is constituted by an assembly of a first part 50 and a second part 56. The first part 50 is a divided part that is approximately integrated with the accommodation wall 26 of the melt reservoir 24 and has an approximately quadrangular tubular shape, and is a frame having an approximately quadrangular columnar opening on an inner side. The second part 56 has an approximately quadrangular columnar shape to be fitted into the opening of the first part 50, and is formed by combining two divided parts 56a having an approximately triangular columnar shape. The second part 56 is fitted into the opening of the first part 50, thereby forming the nozzle portion 34.

The first part 50 having an approximately quadrangular tubular shape protrudes from an approximately central portion of the bottom outer surface 28 of the accommodation wall 26 that constitutes the melt reservoir 24, and constitutes the nozzle outer side surface 37 of the nozzle portion 34. As illustrated in FIG. 2 and FIG. 3, the nozzle hole 36 is formed between the first part 50 and the second part 56, and between the divided parts 56a of the second part 56.

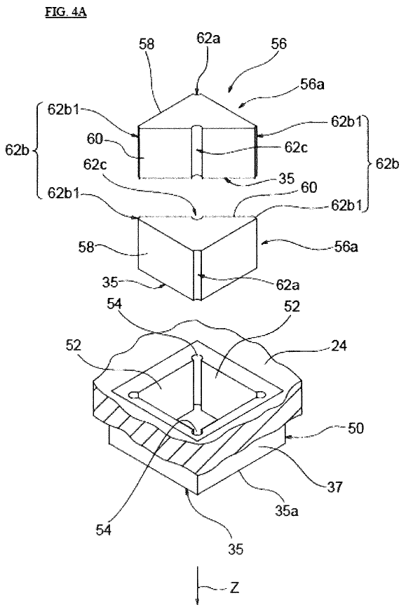

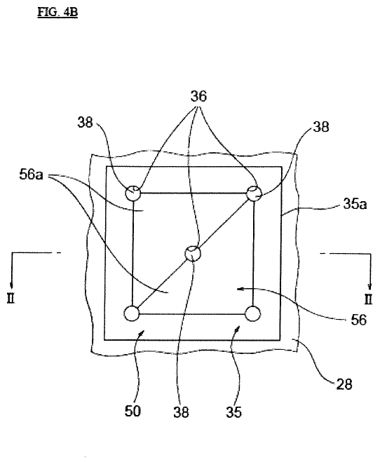

As illustrated in FIG. 4A, grooves 54 leading to the lower end surface 35 from the melt reservoir 24 are formed in four corners of an inner peripheral surface (inner side surface) 52 of an opening of the first part 50 having an approximately quadrangular tubular shape. A cross-section of each of the grooves 54 has a partial shape of a circle (an arc shape of approximately ¾ of the circle). Grooves 62a and 62b in which a cross-section has a partial shape of a circle (an arc shape that becomes a nozzle hole by complementing the arc of the groove 54) are formed in four corners of the second part 56 having a quadrangular columnar shape at positions corresponding to the grooves 54 in a direction that is approximately parallel to the pulling-down direction Z (may be slightly inclined. The same shall apply hereinafter).

Note that, each of two grooves 62a is formed in an intersecting corner of a pair of outer side surfaces 58 (one end of the outer side surfaces 58) of each of the two divided parts 56a having an approximately triangular columnar shape, and other two grooves 62b are formed by combining matching surfaces 60 and 60 of the divided parts 56a. The grooves 62b are formed by combining divided grooves 62b1 which are formed in both ends of the matching surfaces 60 of the two divided parts 56a having an approximately triangular columnar shape. The divided grooves 62b1 are formed in intersecting corners of the matching surfaces 60 and the outer side surface 58 along a direction that is approximately parallel to the pulling-down direction Z.

In addition, a groove 62c is formed in the middle of each of the matching surfaces 60 (in the vicinity of the center in the drawing) of the divided parts 56a of the second part 56 along a direction that is approximately parallel to the pulling-down direction Z. With regard to the grooves 62c, when the matching surfaces 60 of the divided parts 56a are assembled, the grooves 62c are combined to form the nozzle hole 36 located at the center as illustrated in FIG. 2.

In this embodiment, the matching surfaces 60 of the pair of divided parts 56a are combined with each other to form the second part 56, and the outer side surface 58 of the second part 56 are combined with the inner side surface 52 of the first part 50 to form the nozzle portion 34. In this regard, the outer side surface 58 of the second part 56 and the inner side surface 52 of the first part 50 can be referred to as “matching surface”. Accordingly, the grooves 54, 62a, 62b, and 62c, which constitute parts of the nozzle holes 36 illustrated in FIG. 2 and are illustrated in FIG. 4A, extend from the melt reservoir 24 to the lower end surface 35 of the nozzle portion 34 in the middle of the matching surfaces 60, 58, and 52, or at end corners, thereby forming parts of inner peripheral surfaces of the nozzle holes 36.

Surface roughness of inner surfaces of the grooves 54, 62a, 62b1, and 62c is polished to 10 μm or less, preferably 5 μm or less, and more preferably 1 μm or less. In addition, the outer side surface 58 and the inner side surface 52, which become matching surfaces in a similar manner as in the matching surfaces 60, have surface roughness similar to or less than the surface roughness of the grooves, and are polished to 10 μm or less, preferably 5 μm or less, and more preferably 1 μm or less. Although not particularly limited, examples of a polishing means include electrolytic polishing, chemical polishing, composite polishing in which the polishing methods and a physical polishing method are combined, and the like.

In the matching surfaces 60 of the divided parts 56a, surface roughness is preferably small at a portion other than the grooves 62c for close contact in order for the melt 30 illustrated in FIG. 2 not to leak. In addition, since the outer side surface 58 of the second part 56 and the inner side surface 52 of the first part 50 become matching surfaces, as in the case of the matching surfaces 60, the surface roughness is preferably small in a portion other than the grooves 62a, 62b1, and 62c for close contact in order for the melt 30 illustrated in FIG. 2 not to leak.

In this embodiment, the inner side surface 52 of the first part 50 is slightly inclined inward from the melt reservoir 24 toward the vicinity of the center of the end surface 35. In addition, the outer side surface 58 of the second part 56 is preferably inclined so as to correspond to the inclination of the inner side surface 52. According to this configuration, it is easy to insert the second part 56 into an opening of the first part 50 from an upper side, and it is possible to suppress the second part 56 from being dropped downward from the first part 50. Note that, in a state in which the second part 56 is combined to the first part 50, a lower end surface of the second part 56 is flush with a lower end surface of the first part 50, and the lower end surfaces integrally constitute the lower end surface 35.

Note that, a wettability improving layer (not illustrated) may be formed on inner surfaces of the grooves 54, 62a, 62b1, and 62c. Examples of the wettability improving layer include an aluminum oxide layer and a rare-earth garnet compound that does not contain aluminum in a rare-earth aluminum and garnet compound, a rare-earth oxide layer contained in the same composition in a rare-earth silicic acid oxide compound, and a fluoride layer (CaF₂ or BaF₂) of an alkali metal contained in the same composition in fluorides containing an alkali-earth metal such as LiCaAlF₆ and BaLiF₃. It is preferable that the wettability improving layer is formed only on the inner surfaces of the grooves 54, 62a, 62b1, and 62c, but it is preferable that the wettability improving layer is also formed on an upper end surface and a lower end surface of the second part 56, and a lower end surface of the first part 50. It is preferable that the melt 30 does not flow to the matching surface 60 and the outer side surface 58 of the divided parts 56a, and the inner side surface 52 of the first part 50, but the wettability improving layer may be formed thereon.

As illustrated in FIG. 4B, in this embodiment, an external shape viewed from the lower end surface 35 of the nozzle portion 34 is a rectangular shape, and the outer peripheral edge 35a of the lower end surface 35 also has a rectangular shape. However, a shape of the outer peripheral edge 35a is not limited to the rectangular shape, and may be a circular shape, a hexagonal shape, other polygonal shapes, an elliptical shape, or other different shapes. The shape of the outer peripheral edge 35a defines a shape of an outer side surface of a crystal manufactured by the μ-PD method using the crucible 4 illustrated in FIG. 2.

In this embodiment, for example, as illustrated in FIG. 4B, the nozzle hole outlet 38 in the lower end surface 35 of the nozzle hole 36 is formed near the center of the lower end surface 35 and four corners. Five pieces of the nozzle hole outlets 38 pass through the nozzle holes 36 illustrated in FIG. 2 and are connected to the corresponding nozzle hole inlets 32.

In this embodiment, a flow passage cross-section of each of the nozzle holes 36 has a circular shape in combination with the inlet 32 and the outlet 38, and each of the nozzle holes 36 extends in parallel to the pulling-down direction Z of a crystal. However, a cross-sectional shape of each of the nozzle hole outlets 38 is not limited to the circular shape, and can be set to a polygonal shape, an elliptical shape, or the other shapes.

The crystal manufacturing device 2 including the crucible 4 of this embodiment as illustrated in FIG. 1 is preferably used in the μ-PD method. A raw material that is put into the melt reservoir 24 of the crucible 4 is heated by the main heater 10 or the like and becomes the melt 30 illustrated in FIG. 2, passes through the nozzle holes 36 of the nozzle portion 34, is drawn out from the nozzle hole outlets 38 by the seed crystal 14, and the seed crystal 14 is pulled down to grow a crystal, thereby obtaining a crystal body.

Next, a method of manufacturing a crystal by using the crystal manufacturing device 2 of this embodiment will be briefly described. In the crystal manufacturing device 2 of this embodiment, first, a raw material of a crystal body to be obtained is put into the melt reservoir 24 of the crucible 4 illustrated in FIG. 1, and the main heater 10 is activated to heat the melt reservoir 24. When the melt reservoir 24 is heated, the raw material is melted and becomes the melt 30 in the melt reservoir 24, and flows from the nozzle hole inlets 32 of the nozzle portion 34 to the nozzle holes 36. The melt 30 passes through the nozzle holes 36 and comes into contact with an upper end of the seed crystal 14 at the nozzle hole outlets 38.

Before or after the heating, the after-heater 16 is also activated to heat the vicinity of the nozzle portion 34. When using the crucible 4 of this embodiment, the melt 30 ejected from the nozzle hole outlets 38 of the nozzle holes 36 formed in the nozzle portion is crystallized due to pulling-down of the seed crystal 14.

In the crucible 4 of this embodiment, since surface roughness of the inner peripheral surface of the nozzle holes 36 is set to a predetermined value or less, flowing-out of the melt from the nozzle holes 36 is stabilized, and the amount of the melt flowing out from the nozzle holes 36 becomes substantially uniform, and thus it is easy to uniformly disperse an additive element into the crystal body. Note that, even in a case where a single nozzle hole 36 is formed in the nozzle end surface 35 of the crucible 4, flowing-out of the melt from the nozzle hole 36 becomes more stable in comparison to a crucible in the related art in which the surface roughness of the inner peripheral surface of the nozzle hole 36 is not managed, and thus it is easy to uniformly disperse the additive element into the crystal body.

In this embodiment, the nozzle portion 34 is an assembly of a plurality of the divided parts 50, 56a, and 56a, and the nozzle holes 36 are formed when the grooves 62a, 62b1, 62c, and 54 formed in the matching surfaces 60, 58, and 52 of the divided parts 50, 56a, and 56a are combined.

The crucible 4 is required to have heat resistance to withstand a temperature of the melt, possibility of inductive heating, and the like, and thus the crucible 4 is constituted, for example, by a metal that is difficult to be machined, or the like in many cases. Therefore, machining of the nozzle holes 36 formed in the crucible 4 becomes difficult, and it is difficult to set the surface roughness of the inner peripheral surface of the nozzle holes 36 to 10 μm or less.

In this embodiment, the grooves 62a, 62b1, 62c, and 54 which constitute the nozzle holes 36 are formed in the matching surfaces 60, 58, and 52 of the divided parts 50, 56a, and 56a, and the divided parts 50, 56a, and 56a are combined to form the nozzle holes 36. Differently from machining of a hole, when machining a groove, since a machining surface is exposed to the outside, it is easy to obtain accuracy of the surface roughness, and it is easy to set the surface roughness to 10 μm or less, 5 μm or less, or 1 μm or less. Accordingly, when the divided parts 50, 56a, and 56a are combined, the grooves 62a, 62b1, 62c, and 54 are combined to form the nozzle holes 36, and it is easy to set the surface roughness of the inner peripheral surface of the nozzle holes 36 to a predetermined value or less.

In this embodiment, a plurality of the grooves 54 are formed in the inner side surface (inner peripheral surface) 52 of the first part 50, and the second part 56 including a plurality of the divided parts 56a is inserted into an opening of the first part 50 to be combined, thereby forming a plurality of the nozzle holes 36. In addition, the second part 56 is formed by combining the plurality of divided parts 56a, and the grooves 62c formed in the matching surfaces 60 are combined to form the nozzle holes 36. Due to machining of the grooves 62a, 62b1, and 54, it is easy to obtain accuracy of surface roughness and it is also easy to make accuracy of the surface roughness of a plurality of grooves substantially uniform. Accordingly, the amount of the melt 30 flowing from the nozzle holes 36 becomes substantially uniform, and thus it is easier to uniformly disperse an additive element into a crystal body.

Furthermore, in this embodiment, the inner side surface 52 of the first part 50 is inclined from the melt reservoir 24 toward a direction close to the center of the lower end surface 35 of the nozzle portion 34, and the outer side surface 58 of the second part 56 is inclined in correspondence with the inner side surface 52 of the first part 50. According to this configuration, when the second part 56 is inserted into the opening of the first part 50 and is dropped down, the second part 56 does not fall down, and the nozzle portion 34 can be easily formed. In addition, the outer side surface 58 of the second part 56 and the inner side surface 52 of the first part 50 become matching surfaces, and the grooves 62a and 62b are formed in the matching surfaces, and thus the nozzle holes 36 inclined toward a direction close to the center of the lower end surface 35 of the nozzle portion 34 from the melt reservoir 24 can be easily formed by combining the first part 50 and the second part 56.

In addition, in this embodiment, the inner peripheral surface of the nozzle holes 36 are coated with the wettability improving layer with high wettability with the melt 30 stored in the melt reservoir 24. According to this configuration, it is easy for the melt 30 to flow out to the lower end surface 35 after passing through the nozzle holes 36, and thus a variation of an additive element in a crystal body can be further effectively suppressed.

In addition, in this embodiment, typically, a hole is not formed by machining a metal that is difficult to be machined. The grooves 62a and 62b are formed in the outer side surface 58 of the divided parts 56a and 56a, the grooves 54 are formed in inner corers of the inner side surface 52 of the first part 50, or the groove 62c is formed in the center of the matching surface 60. In addition, the divided parts are combined to form the nozzle holes 36. Accordingly, it is easy to machine the surface roughness of the inner peripheral surface of the nozzle holes 36 with accuracy of a predetermined value or less.

The crystal body (preferably, a single crystal) according to this embodiment is manufactured by using the crucible 4 described above, and may contain an additive element having a segregation coefficient less than 1. A crystal that is grown by using the crucible 4 according to this embodiment has a shape close to an ideal columnar shape. In addition, a different phase is less likely to be mixed in the crystal body, and the crystal body is further less likely to be polycrystallized.

In addition, when using the crucible 4 according to this embodiment, a concentration distribution of a composition (containing an activator) in the crystal body that is grown from the nozzle hole outlets 38 becomes substantially uniform, particularly, in a plane orthogonal to the pulling-down direction Z. In addition, the concentration distribution becomes substantially uniform also in a plane parallel to the pulling-down direction Z. For example, in a case of manufacturing YAG:Ce by using the device 2 of this embodiment, it is possible to obtain a crystal body of YAG:Ce or the like in which an activator such as Ce is uniformly dispersed.

In addition, the method of manufacturing a crystal body according to this embodiment includes a process of causing the melt 30 that becomes a raw material of a crystal to flow out from the nozzle hole outlets 38 of the nozzle holes 36 which are formed in the nozzle portion 34 and in which surface roughness of an inner peripheral surface is 10 μm or less. According to the manufacturing method of this embodiment, even in a case where an additive element having a segregation coefficient less than 1 is contained, it is possible to obtain a crystal body in which a concentration variation of the additive element is suppressed. In the crystal body obtained by the manufacturing method of this embodiment, crystallinity is improved, a single crystal is likely to be obtained, polycrystallization can be suppressed, and occurrence of cracks is also suppressed.

In addition, a crystal body that is obtained by using the manufacturing method of this embodiment is preferably used as an optical element. Furthermore, when using the method of this embodiment, stabilization of crystal grown is secured, and shape accuracy of the crystal body is improved. Accordingly, a machining loss of the crystal body decreases, and a crystal body with high quality can be manufactured with high efficiency.

### Second Embodiment

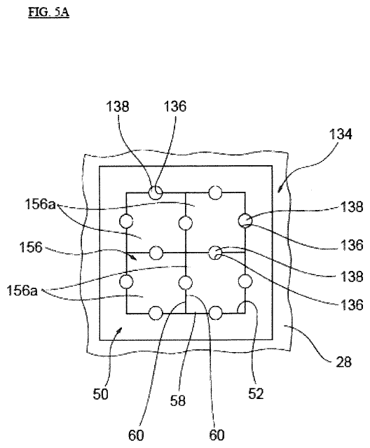

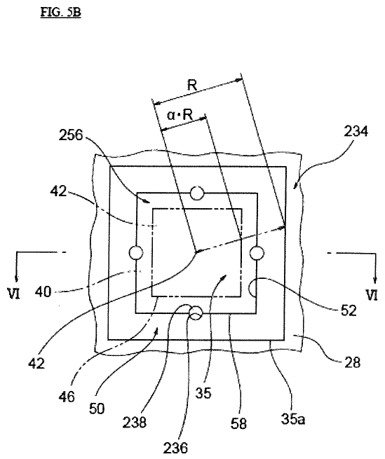

As illustrated in FIG. 5A, a crystal manufacturing device according to this embodiment is different from the first embodiment only in divided parts (second part) of the nozzle portion 34, and description of a common portion will be omitted. Hereinafter, different portions will be mainly described in detail. A portion that is not described below is similar to description of the first embodiment.

The nozzle portion 34 of a crucible according to this embodiment is an assembly of the first part 50 and a second part 156. In the second part 156, four quadrangular columnar divided parts 156a are combined and the resultant assembly is inserted into an inner side of the first part 50 having a quadrangular tubular shape to form the nozzle portion 34.

A nozzle hole 136 is formed between an outer side surface 58 (matching surface) of the second part 156 and the inner side surface 52 (matching surface) of the first part 50, and between matching surfaces 60 of the divided parts 156a which constitute the second part 156. The nozzle hole 136 is formed by combining grooves formed in the matching surfaces of the parts in a similar manner as in the first embodiment. An arrangement and the number of the nozzle hole 136 and a nozzle hole outlet 138 can be freely determined.

### Third Embodiment

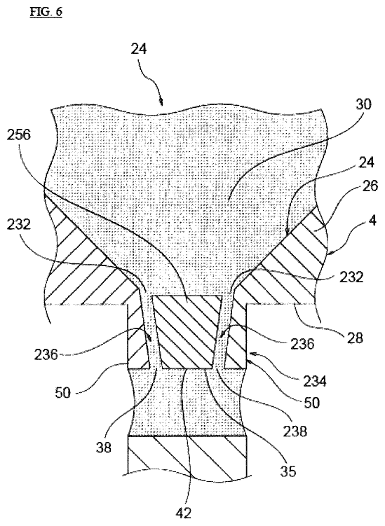

As illustrated in FIG. 5B and FIG. 6, the crystal manufacturing device according to this embodiment is different from the first or second embodiment only in divided parts (a first part and a second part) of a nozzle portion 34, and thus description of a common portion will be omitted. Hereinafter, different portions will be mainly described in detail. A portion that is not described below is similar to description of the first or second embodiment.

A nozzle portion 34 of a crucible according to this embodiment is an assembly of the first part 50 and a single second part 256. The second part 256 is a divided part having a size of being inserted into an inner opening of the first part 50 having a quadrangular frame shape through just fit. The second part 256 is fitted into an inner side of the first part 50 to form the nozzle portion 34.

Nozzle holes 236 are formed between an outer side surface 58 (matching surface) of the second part 256 and the inner side surface 52 (matching surface) of the first part 50. The nozzle holes 236 are formed by combining grooves formed in the matching surfaces of the parts in a similar manner as in the first or second embodiment. An arrangement and the number of the nozzle holes 236 can be freely determined.

In this embodiment, the outer side surface 58 of the second part 256 illustrated in FIG. 5B is inclined from the melt reservoir 24 illustrated in FIG. 6 toward the lower end surface 35 of the nozzle portion 34 in a direction close to the center 42 of the lower end surface 35 of the nozzles. In addition, the inner side surface 52 of the first part 50 is also inclined in conformity to the inclination. As a result, as illustrated in FIG. 6, the nozzle holes 236 according to this embodiment are inclined from nozzle hole inlets 232 toward nozzle hole outlets 238 and toward a direction close to the center 42 of the end surface 35.

In addition, according to this embodiment, in the nozzle holes 236, the entirety of a flow passage is inclined in order for the nozzle hole outlets 238 to be closer to the center of the lower end surface 35 in comparison to the nozzle hole inlets 232 opened to the melt reservoir 24. According to this configuration, a raw material melt ejected from the nozzle hole outlets 38 is likely to be directed to an inner side from an outer side of a crystal along a crystal growth plane.

In addition, in this embodiment, as illustrated in FIG. 5B, the nozzle hole outlets 238 in the lower end surface 35 of the nozzle holes 236 are arranged in a nozzle hole forming region 40 located close to the outer peripheral edge 35a of the lower end surface 35. In addition, in this embodiment, the nozzle hole outlets 238 are constituted by a plurality of individual outlets 238 formed intermittently with predetermined interval along a peripheral direction within a range of the nozzle hole forming region 40. The plurality of outlets 238 are connected to a plurality of corresponding nozzle hole inlets 232 after passing through the plurality of individual nozzle holes 236 illustrated in FIG. 6.

In this embodiment, a flow passage cross-section of each of the nozzle holes 236 has a circular shape in combination with the inlets 232 and the outlets 238, and the flow passage cross-section of the nozzle hole 236 is constant from the inlets 232 to the outlets 238, but it is not necessary for the flow passage cross-section to be constant. For example, in this embodiment, only the outlets 238 may be constituted by a plurality of individual outlets 238 along a peripheral direction, and the nozzle holes 236 may be set as a single ring-shaped hole connecting the plurality of outlets 238 along the peripheral direction. In addition, with regard to the nozzle hole inlets 232 may be set as a single ring-shaped opening connecting the plurality of outlets 238 along the peripheral direction in a similar manner as in the nozzle holes 236.

In this case, in the vicinity of the melt reservoir 24, a ring-shaped gap or opening may be formed between the matching surfaces of the first part 50 and the second part 256. The ring-shaped gap or opening may be approximately parallel to the pulling-down direction Z. Alternatively, in the vicinity of the melt reservoir 24, the second part 256 may not be formed, and a columnar space may exist. However, in the vicinity of the lower end surface 35 of the nozzle portion 234, the matching surfaces of the first part 50 and the second parts 256 are preferably in contact with each other in a portion other than the nozzle holes 236 in order for the melt not to be leaked, but the melt may be slightly leaked. In addition, a cross-sectional shape of the individual nozzle hole outlets 238 may be set to have a polygonal shape, an elliptical shape, and other shapes without limitation to a circular shape. The deformation is also applicable to the first embodiment and the second embodiment.

As illustrated in FIG. 5B, in this embodiment, a region including the center 42 of the lower end surface 35 located on an inner side of the nozzle hole forming region 40 is a nozzle hole not-formed region 44 in which the nozzle hole outlets 38 are substantially not formed. Note that, in this embodiment, the center 42 of the lower end surface 35 represents the geometric center or the center of gravity of a planer shape of the lower end surface 35. For example, in a case where a shape of the outer peripheral edge 35a of the lower end surface 35 is a circle, the center 42 of the lower end surface 35 represents the center of the circle. In addition, as illustrated in FIG. 5B, in a case where the shape of the outer peripheral edge 35a is a polygonal shape such as a square and a hexagon, an elliptical shape, or the other different shapes, the center 42 represents the center of gravity of the lower end surface 35. The lower end surface 35 includes a lower end surface of the first part 50 and a lower end surface of the second part 256.

As illustrated in FIG. 5B, the nozzle hole forming region 40 is located within a range between a virtual boundary line 46 that connects ½ of a distance R from the center 42 of the lower end surface 35 to the outer peripheral edge 35a in a peripheral direction, and the outer peripheral edge 35a. More preferably, the nozzle hole forming region 40 is located within a range between the virtual boundary line 46 that connects ⅔ (more preferably ¾) of the distance R from the center 42 of the lower end surface 35 to the outer peripheral edge 35a in a peripheral direction, and the outer peripheral edge.

Note that, the distance from the center 42 of the virtual boundary line 46 can be expressed as α×R. α is preferably ½ or greater, more preferably ⅔ or greater, and still more preferably ¾. The upper limit of a is less than 1, and is determined so that the nozzle hole outlets 38 are formed within a range of the nozzle hole forming region 40 expressed by (R−α×R). The nozzle hole outlets 238 are preferably formed close to the outer peripheral edge 35a as much as possible.

An inner diameter (or an opening area) of the nozzle hole outlets 238 is not particularly limited, and is determined so that the nozzle hole outlets 238 are within the range (R−α×R) of the nozzle hole forming region 40. In a case where the nozzle hole outlets 238 have a circular shape, the inner diameter of the outlets 238 is, for example, approximately 1/10 to 9/10 of (R−α×R). In addition, although not particularly limited, the number of the nozzle hole outlets 238 arranged within the range of the nozzle hole forming region 40 is, for example, preferably 4 or greater along a peripheral direction, more preferably 6 or greater, and still more preferably 8 or greater.

In a case where the shape of the outer peripheral edge 35a is a circle, the shape of the virtual boundary line 46 also becomes a circle, and the size of a radius of the circle of the virtual boundary line 46 becomes a times the distance (radius) R of the outer peripheral edge 35a. Furthermore, in a case where the shape of the outer peripheral edge 35a is a hexagon, the shape of the virtual boundary line 46 also becomes a hexagon, and the shape of the virtual boundary line 46 becomes a similar shape that is a times the shape of the outer peripheral edge 35a. In addition, as illustrated in FIG. 5B, in a case where the shape of the outer peripheral edge 35a is a square, the shape of the virtual boundary line 46 also becomes a square, and the shape of the virtual boundary line 46 becomes a similar shape that is a times the shape of the outer peripheral edge 35a. Even in a case where the shape of the outer peripheral edge 35a is the other different shapes, the shape of the virtual boundary line 46 becomes a similar shape that is a times the shape of the outer peripheral edge 35a.

Note that, an inner region (a region including the center 42) of the virtual boundary line 46 becomes the nozzle hole not-formed region 44, and the nozzle hole outlet 38 are substantially not formed in the region. The meaning of “nozzle hole outlets 38 are substantially not formed” will be described later.

When using the crucible 4 of this embodiment, a melt that is pulled down from the nozzle hole outlets 38 disposed in the nozzle hole forming region 40 located close to the outer peripheral edge 35a of the end surface 35 of the nozzle portion 34 by the seed crystal 14 flows toward the center 42 of the nozzle hole not-formed region 44 along the lower end surface 35, and crystal growth is performed.

That is, when using the crucible 4 of this embodiment, crystal growth starts from a site close to the outer peripheral edge 35a of the end surface 35 of the nozzle portion 34 and proceeds toward an inner side. Accordingly, even in a case where an additive element having a segregation coefficient less than 1 is contained in the melt, the additive element is less likely to be mixed in a crystal and is concentrated during a growing process, and thus it is possible to effectively suppress a phenomenon in which the additive element segregates to an outer edge portion at an initial stage of growing.

Accordingly, in a crystal body obtained by using the crucible 4 of this embodiment, even in a case where an additive element having a segregation coefficient less than 1 is contained, surplus segregation of the additive element (dopant) at a site close to an outer side surface of the crystal body is suppressed. In the crystal body of this embodiment, crystallinity is improved, a single crystal is likely to be obtained, polycrystallization can be suppressed, and occurrence of cracks is also suppressed.

In addition, the crystal body obtained by using the crucible 4 of this embodiment can suppress dilution of the concentration of the additive element (dopant) in the vicinity of the center of the crystal body, and an effect of adding a dopant to the crystal body increases. The obtained crystal body is preferably used as an optical element. Furthermore, when using the crucible 4 of this embodiment, stability of crystal growth is secured, and shape accuracy of the crystal body is improved. Accordingly, a machining loss of the crystal body decreases, and a crystal body with high quality can be manufacture with high efficiency.

In addition, in this embodiment, the nozzle hole forming region 40 is disposed close to the outer peripheral edge 35a in the lower end surface 35 of the nozzle portion 34, and an inner side thereof is set as the nozzle hole not-formed region 44. Accordingly, after the raw material melt passes through the nozzle hole outlets 38, a flow of the melt moving along a crystal growth plane is likely to be directed toward an inner side from an outer peripheral side of a crystal. As a result, a crystal that is grown by using the crucible 4 according to this embodiment has a shape close to an ideal columnar shape. In addition, a different phase is less likely to be mixed in the crystal body, and the crystal body is further less likely to be polycrystallized.

Note that, in this embodiment, description of “nozzle hole outlet is substantially not formed” in the nozzle hole not-formed region 44 represents that a nozzle hole outlet smaller than an inner diameter of the nozzle hole outlets 38 formed in the nozzle hole forming region 40 can be slightly formed. Alternatively, the description represents that even though the inner diameter of the nozzle hole outlets 38 is the same in each case, the nozzle hole outlets 38 can be slightly formed in the nozzle hole not-formed region 44 in a number less than the number of the nozzle hole outlets 38 formed in the nozzle hole forming region 40, for example, in a number less than the number by approximately 1/10 or less.

### EXAMPLES

Hereinafter, the present invention will be further described on the basis of detailed example, but the present invention is not limited to the examples.

### Example 1

A fluorescent substance formed from a single crystal of Ce:YAG (Ce doped YAG) was manufactured by using the crystal manufacturing device 2 illustrated in FIG. 1. The crucible 4 used in growth was formed from iridium and had a cylindrical shape having an outer diameter of 20 mm, an inner diameter of 18 mm, and a height of 50 mm. The device 2 included the nozzle portion 34 having a structure illustrated in FIG. 2 to FIG. 4B, the nozzle hole outlets 38 of a total of five nozzle holes 36 were arranged at four corners of the nozzle end surface 35 at a position on an inner side by 1.0 mm from the outer peripheral edge 35a and at the center of the nozzle end surface 35, and penetrated in the vertical direction (pulling-down direction). The nozzle end surface 35 has a square shape (R=2.5 mm) having dimension of 5.0 mm×5.0 mm, and an inner diameter of the nozzle holes 36 was 0.4 mm.

(Evaluation of Surface Roughness) The inner peripheral surface 36a of the nozzle holes 36 was measured ten times with respect to the inner peripheral surface 36a of the nozzle holes 36 by using a laser microscope (LEXT-OLS4100) manufactured by Olympus Corporation, and arithmetic mean roughness Ra was obtained.

The arithmetic mean roughness Ra of the inner peripheral surface 36a of the nozzle holes 36 according to this example was 6 to 9 μm.

(Preparation of Specimen) Respective oxide powders of Al₂O₃, Y₂O₃, and CeO₂ with purity of 99.99% were blended in a composition ratio of Y₂O₃:Al₂O₃=3.0:5.0, or CeO₂/(CeO₂+(1/2)Y₂O₃)=0.01 in terms of a molar ratio to obtain a raw material in a total amount of 10 g, and the resultant raw material was set as a raw material for crystal growth. The crucible 4 filled with the same raw material was provided in the single crystal growing device 2, and was heated up to approximately 2000° C. for one hour.

In an N₂ gas flow atmosphere, a Y3Al5O12 single crystal in which a crystal orientation <111> is set as a longitudinal direction was used as the seed crystal 14, and as illustrated in FIG. 2, a tip end of the seed crystal 14 was brought into contact with the nozzle portion 34 provided in the lower end of the crucible 4, after the raw material melt flowing out from the nozzle hole outlets 38 of the nozzle portion 34 wets and spreads on the tip end of the seed crystal 14, the seed crystal 14 was gradually lowered to perform crystal growth at a pulling-down rate of 0.20 mm per minute.

A Ce:YAG single crystal having a quadrangular columnar shape of approximately 5 mm square and 40 mm in length was obtained. The single crystal was deep yellow and transparent, and thus precipitates such as an inclusion were not observed in the crystal with naked eyes. Four side surfaces of the crystal body were smooth, and a cross-section orthogonal to the pulling-down direction had an approximately square shape over the entirety of the crystal.

With respect to the obtained crystal body, specimens for evaluation were sampled as follows, and the following evaluation was performed.

(Sampling of Specimen for Evaluation)

Ten crystals grown by a micro pulling-down method were grown. Three samples for evaluation were prepared from one crystal at positions different in the pulling-down direction. The respective samples were prepared by cutting a specimen at a cut plane orthogonal to the pulling-down direction in a state in which an outer side surface of the crystal body during the pulling-down growth is set as an outer peripheral edge. Furthermore, both surfaces were mirror polished so that the inside of the crystal can be observed, thereby preparing a flat specimen for evaluation in a thickness of approximately 1 mm. A composition variation of the grown crystal was evaluated by using a total of 30 samples.

(Evaluation of Composition Variation)

With regard to a composition distribution inside the grown crystal, an additive element Ce was evaluated by laser ablation ICP mass spectrometry by using an ICP-MS analyzer (7500S, manufactured by Agilent Technologies, Inc.). Quartiles were statically obtained from composition distribution measurement results of the respective samples, and comparison evaluation for a deviation in concentration of Ce was performed.

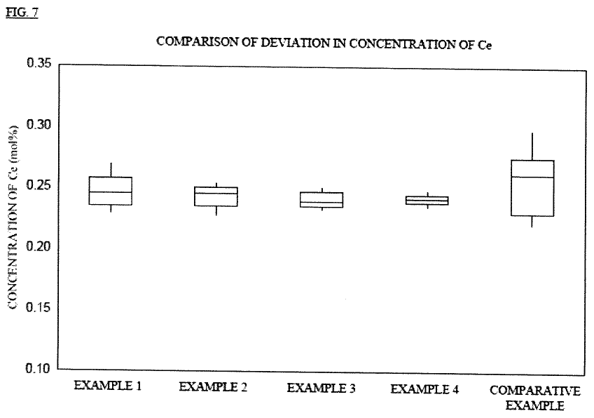

It was determined that the smaller a difference between the maximum value and the minimum value in the samples is, the smaller the composition variation is. Results obtained with respect to the 30 samples are shown in FIG. 7.

### Example 2

A Ce:YAG single crystal was grown by the micro pulling-down method by using a crucible including the same nozzle portion 34 as in Example 1 except that the arithmetic mean roughness Ra of the inner peripheral surface 36a of the nozzle holes 36 is within a range of 3 to 4 μm.

Crystal growth was performed by the same raw material and under the same growing conditions as in Example 1, and the same evaluation as in Example 1 was performed. Results are shown in FIG. 7.

### Example 3

A Ce:YAG single crystal was grown by the micro pulling-down method by using a crucible that is formed from the same material and has the same shape as the crucible 1 used in Example 1 except that the arithmetic mean roughness Ra of the inner peripheral surface 36a of the nozzle holes 36 is within a range of 0.6 to 0.8 μm.

Crystal growth was performed by the same raw material and under the same growing conditions as in Example 1, and the same evaluation as in Example 1 was performed. Results are shown in FIG. 7.

### Example 4

With respect to a crucible having the same specifications as in Example 3, the inner peripheral surface 36a of the nozzle holes 36 was coated with Al₂O₃ at a film forming temperature of 150° C. with an atomic layer deposition (ALD) device (AFALD-8, manufactured by JSW-AFTY. CO. JP) by using trimethyl aluminum (TMA) as a precursor gas and oxygen (O₂) as an oxidizing agent. A Ce:YAG single crystal was grown by the micro pulling-down method by using a crucible that is formed from the same material and has the same shape as in Example 3 except that the inner peripheral surface 36a of the nozzle holes 36 is coated with Al₂O₃.

Crystal growth was performed by the same raw material and under the same growing conditions as in Example 1, and the same evaluation as in Example 1 was performed. Results are shown in FIG. 7.

### Comparative Example 1

A crucible including a typical nozzle portion was used, and the nozzle holes were formed by wire electric discharge machining. The arithmetic mean roughness Ra of the inner peripheral surface 36a of the nozzle holes 36 was within a range of 12 to 18 μm. Crystal growth was performed by using the same raw material and device, and under the same atmosphere and growing conditions as in Example 1, and the same evaluation as in Example 1 was performed. Results are shown in Table 7.

Evaluation

As illustrated in FIG. 7, from the results in Examples 1 to 4, it could be seen that a difference between a maximum value and a minimum value of the concentration of Ce in samples is smaller and a composition variation is smaller in comparison to results in Comparative Example 1. Particularly, satisfactory results were obtained in the order of Examples 4, 3, 2, and 1.

### EXPLANATIONS OF LETTERS OR NUMERALS

2 CRYSTAL MANUFACTURING DEVICE
4 CRUCIBLE
6 REFRACTORY FURNACE (REFRACTORY MATERIAL)
8 OUTER CASING
10 MAIN HEATER
12 SEED CRYSTAL HOLDING JIG
14 SEED CRYSTAL
16 AFTER-HEATER
24 MELT RESERVOIR
26 ACCOMMODATION WALL
28 BOTTOM OUTER SURFACE
30 MELT
32, 232 NOZZLE HOLE INLET
34, 134, 234 NOZZLE PORTION
35 END SURFACE
35a OUTER PERIPHERAL EDGE
36, 136, 236 NOZZLE HOLE
36a INNER PERIPHERAL SURFACE
37 OUTER SIDE SURFACE
38, 138, 238 NOZZLE HOLE OUTLET
40 NOZZLE HOLE FORMING REGION
42 CENTER
44 NOZZLE HOLE NOT-FORMED REGION
46 VIRTUAL BOUNDARY LINE
50 FIRST PART (DIVIDED PART)
52 INNER SIDE SURFACE (MATCHING SURFACE)
54 GROOVE
56, 156, 256 SECOND PART (DIVIDED PART)
56a, 156a, 256a DIVIDED PART
58 OUTER SIDE SURFACE (MATCHING SURFACE)
60 MATCHING SURFACE
62a, 62b, 62c GROOVE

What is claimed is:

1. A crucible comprising:
a melt reservoir storing a melt to be a raw material of a crystal; and
a nozzle portion controlling a shape of the crystal,
wherein the nozzle portion includes a nozzle hole guiding the melt from the melt reservoir to an end surface of the nozzle portion, and
a surface roughness of an inner peripheral surface of the nozzle hole is 10 μm or less.

2. The crucible according to claim 1,
wherein the nozzle portion is an assembly of divided parts, and
the nozzle holes are formed by combining grooves formed in matching surfaces of the divided parts.

3. The crucible according to claim 2,
wherein the grooves extend from the melt reservoir to the end surface of the nozzle portion in the middle of the matching surfaces or at end corners, and
the grooves define a part of the inner peripheral surface of the nozzle holes.

4. The crucible according to claim 2,
wherein the divided parts comprise a first part having an outer side surface of the nozzle portion, and a second part that is combined to the first part.

5. The crucible according to claim 4,
wherein the first part is integrated with the melt reservoir, and
the second part is formed to be detachable from the melt reservoir.

6. The crucible according to claim 4,
wherein an inner side surface of the first part is inclined from the melt reservoir toward a direction close to the center of the end surface of the nozzle portion,
an outer side surface of the second part is inclined in correspondence with the inner side surface of the first part, and
the inner side surface of the first part and the outer side surface of the second part are faced to each other and are combined.

7. The crucible according to claim 1,
wherein the inner peripheral surface is coated with a wettability improving layer having high wettability with the melt stored in the melt reservoir.

8. The crucible according to claim 1,
wherein the crucible is made from iridium, rhenium, molybdenum, tantalum, tungsten, platinum, or alloys thereof.

9. A crystal body manufactured by using the crucible according to claim 1.

10. An optical element comprising the crystal body according to claim 9.
